(19) United States
(12) Patent Application Publication
(10) Pub. No.: US 2025/0031396 A1
(43) Pub. Date: Jan. 23, 2025

(54) SEMICONDUCTOR DEVICE

(71) Applicant: Mitsubishi Electric Corporation, Tokyo (JP)

(72) Inventor: Kazuya KONISHI, Tokyo (JP)

(73) Assignee: Mitsubishi Electric Corporation, Tokyo (JP)

(21) Appl. No.: 18/646,698

(22) Filed: Apr. 25, 2024

(30) Foreign Application Priority Data
Jul. 21, 2023 (JP) 2023-118764

(51) Int. Cl. H01L 29/739; H01L 27/06; H01L 29/16; H01L 29/20; H01L 29/24; H01L 29/423; H01L 29/43; H01L 29/78

(52) U.S. Cl. CPC H01L 29/7397; H01L 27/0658; H01L 27/0664; H01L 28/20; H01L 29/4236; H01L 29/42364; H01L 29/42376; H01L 29/435; H01L 29/7813; H01L 29/1608; H01L 29/2003; H01L 29/24

(57) ABSTRACT

A semiconductor device includes a gate electrode embedded in each of a plurality of first trenches through an insulating film. The gate electrode includes a first gate electrode electrically connected to a first gate pad and a second gate electrode electrically connected to a second gate pad. A charge period and a discharge period of gate capacitance parasitic on the second gate electrode are shorter than a charge period and a discharge period of gate capacitance parasitic on the first gate electrode, respectively.

### BACKGROUND OF THE INVENTION

### Field of the Invention

The present disclosure relates to a semiconductor device.

### Description of the Background Art

Japanese Patent No. 5742672 discloses a semiconductor device in which a first gate electrode and a second gate electrode are provided on one semiconductor substrate. In the semiconductor device described in Japanese Patent No. 5742672, the second gate electrode is turned off at timing earlier than the first gate electrode at the time of turn-off, and the second gate electrode is turned on at timing later than the first gate electrode at the time of turn-on. This reduces a switching loss.

In the semiconductor device described in Japanese Patent No. 5742672, it is not considered that gate capacitance parasitic on the second gate electrode is charged and discharged at high speed. For this reason, there is a problem that a period during which on-voltage is low is short and a conduction loss is large. Specifically, when the second gate electrode is turned on, an n-type accumulation layer is formed around the second gate electrode and the accumulation layer serves as a hole barrier, so that hole density in a drift layer can be increased to reduce the on-voltage. When the charge-discharge time of the second gate electrode is long, the period during which the second gate electrode is in an on-state is shortened, and there is a problem that the conduction loss is worsened.

### SUMMARY

An object of the technology of the present disclosure is to improve the conduction loss in the semiconductor device including the first gate electrode and the second gate electrode.

A semiconductor device of the present disclosure includes a semiconductor substrate, an upper-surface electrode, a lower-surface electrode, a first gate pad, and a second gate pad. The semiconductor substrate includes a first main surface and a second main surface opposed to the first main surface. The upper-surface electrode is formed on the first main surface of the semiconductor substrate. The lower-surface electrode is formed on the second main surface of the semiconductor substrate. The second gate pad is controlled independently of the first gate pad. The semiconductor substrate includes a first-conductivity-type drift layer, a second-conductivity-type base layer, a first-conductivity-type source layer, and a plurality of first trenches. The base layer is formed on the first main surface side of the drift layer. The source layer is formed on the first main surface side of the base layer. The plurality of first trenches penetrate the base layer from the source layer to reach the drift layer. The semiconductor device includes a gate electrode that is embedded in each of the plurality of first trenches through an insulating film. The gate electrode includes a first gate electrode and a second gate electrode. The first gate electrode is electrically connected to the first gate pad. The second gate electrode is electrically connected to the second gate pad. A charge period and a discharge period of gate capacitance parasitic on the second gate electrode are shorter than a charge period and a discharge period of gate capacitance parasitic on the first gate electrode, respectively.

According to the semiconductor device of the present disclosure, the charge-discharge period of the gate capacitance parasitic on the second gate electrode is shorter than the charge-discharge period of the gate capacitance parasitic on the first gate electrode. Accordingly, the on-period of the second gate electrode can be lengthened. As a result, the period during which the on-voltage is low becomes longer, and the conduction loss is improved.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a top view of a semiconductor device according to a first preferred embodiment;

FIG. 2 is a sectional view illustrating the semiconductor device according to the first preferred embodiment taken along line A-A in FIG. 1;

FIG. 3 is a view illustrating drive timing of the semiconductor device;

FIG. 4 is a sectional view illustrating a semiconductor device according to a first modification of the first preferred embodiment;

FIG. 5 is a sectional view illustrating a semiconductor device according to a second modification of the first preferred embodiment;

FIG. 6 is a sectional view illustrating a semiconductor device according to a third modification of the first preferred embodiment;

FIG. 7 is a sectional view illustrating a semiconductor device according to a second preferred embodiment;

FIG. 8 is a sectional view illustrating a semiconductor device according to a third preferred embodiment;

FIG. 9 is a sectional view illustrating a semiconductor device according to a first modification of the third preferred embodiment;

FIG. 10 is a sectional view illustrating a semiconductor device according to a second modification of the third preferred embodiment;

FIG. 11 is a sectional view illustrating a semiconductor device according to a third modification of the third preferred embodiment;

FIG. 12 is a sectional view illustrating a semiconductor device according to a fourth modification of the third preferred embodiment;

FIG. 13 is a sectional view illustrating a semiconductor device according to a fifth modification of the third preferred embodiment;

FIG. 14 is a sectional view illustrating a semiconductor device according to a sixth modification of the third preferred embodiment;

FIG. 15 is a sectional view illustrating a semiconductor device according to a fourth preferred embodiment;

FIG. 16 is a sectional view illustrating a semiconductor device according to a first modification of the fourth preferred embodiment;

FIG. 17 is a top view illustrating a semiconductor device according to a fifth preferred embodiment;

FIG. 18 is a top view illustrating a semiconductor device according to a first modification of the fifth preferred embodiment;

FIG. 19 is a top view illustrating a semiconductor device according to a sixth preferred embodiment;

FIG. 20 is a sectional view illustrating the semiconductor device according to the sixth preferred embodiment taken along line B-B in FIG. 16;

FIG. 21 is a view illustrating drive timing of the semiconductor device according to the sixth preferred embodiment;

FIG. 22 is a sectional view illustrating a semiconductor device according to a first modification of the sixth preferred embodiment;

FIG. 23 is a sectional view illustrating a semiconductor device according to a seventh preferred embodiment;

FIG. 24 is a view illustrating drive timing of the semiconductor device according to the seventh preferred embodiment; and

FIG. 25 is a sectional view illustrating a semiconductor device according to a first modification of the seventh preferred embodiment.

### DESCRIPTION OF THE PREFERRED EMBODIMENTS

In the following description, signs n and p represent a conductivity type of a semiconductor. In the present disclosure, a first conductivity type is an n-type, and a second conductivity type is a p-type. However, the first conductivity type may be the p-type, and the second conductivity type may be the n-type. In addition, n-indicates that impurity concentration is lower than n, and n+ indicates that the impurity concentration is higher than n. Similarly, p− indicates that the impurity concentration is lower than p, and p+ indicates that the impurity concentration is higher than p.

### A. First Preferred Embodiment

### <A-1. Configuration>

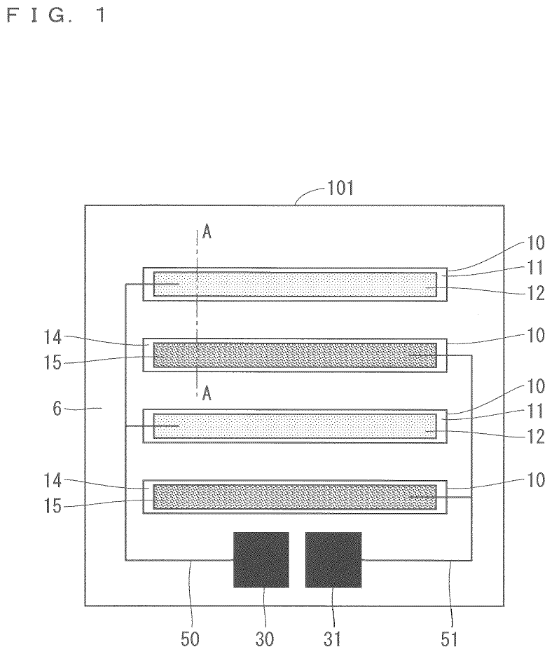

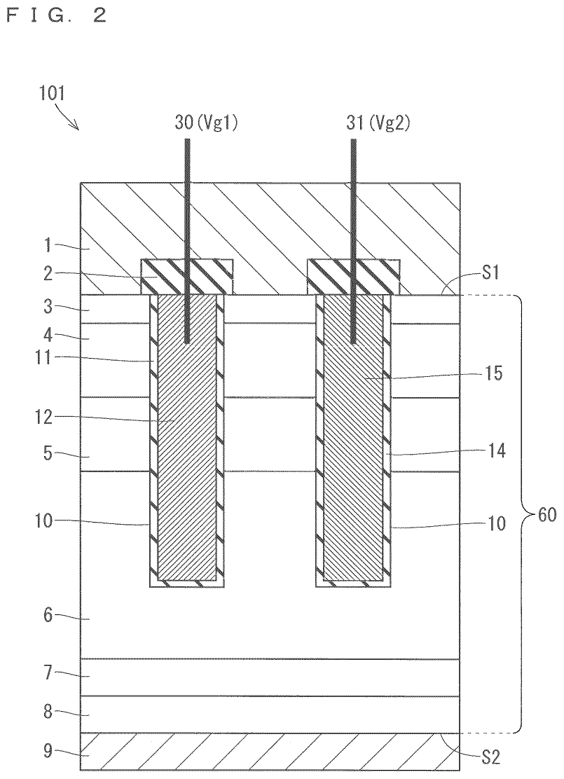

FIG. 1 is a top view illustrating a semiconductor device 101 according to a first preferred embodiment. However, an interlayer insulating film 2 and an emitter electrode 1 are not illustrated in FIG. 1. FIG. 2 is a cross-sectional view illustrating the semiconductor device 101 taken along line A-A in FIG. 1. The semiconductor device 101 configures an insulated gate bipolar transistor (IGBT).

As illustrated in FIG. 2, the semiconductor device 101 includes a semiconductor substrate 60. The semiconductor substrate 60 has a first main surface S1 and a second main surface S2 that is a main surface opposite the first main surface S1. The semiconductor substrate 60 includes an n+-type source layer 3, a p-type base layer 4, an n-type carrier accumulation layer 5, an n−-type drift layer 6, an n-type buffer layer 7, and a p-type collector layer 8. The n-type carrier accumulation layer 5 is provided on a side of the first main surface S1 of the n−-type drift layer 6. The p-type base layer 4 is provided on the side of the first main surface S1 of the n-type carrier accumulation layer 5. The n+-type source layer 3 is provided on the side of the first main surface S1 of the p-type base layer 4. The n-type buffer layer 7 is provided on the side of the second main surface S2 of the n-type drift layer 6. The p-type collector layer 8 is provided on the side of the second main surface S2 of the n-type buffer layer 7.

A plurality of trenches 10 that penetrate the n+-type source layer 3, the p-type base layer 4, and the n-type carrier accumulation layer 5 from an upper surface of the n+-type source layer 3 to reach the n−-type drift layer 6 are formed. The plurality of trenches 10 extend in the same direction as illustrated in FIG. 1. Although four trenches 10 are illustrated in FIG. 1, the number of trenches 10 is not limited to four.

Although not illustrated in FIG. 2, a p+-type contact layer is also provided on the p-type base layer 4. The n+-type source layer 3 and the p+-type contact layer are alternately provided along an extending direction of each trench 10. The n+-type source layer 3 is a semiconductor layer containing, for example, arsenic or phosphorus as n-type impurities. The concentration of the n-type impurity in the n+-type source layer 3 is greater than or equal to 1.0×10¹⁷/cm³ and less than or equal to 1.0×10²⁰/cm³. The p+-type contact layer is a semiconductor layer containing, for example, boron or aluminum as a p-type impurity. The concentration of the p-type impurity in the p+-type contact layer is greater than or equal to 1.0×10¹⁵/cm³ and less than or equal to 1.0×10²⁰/cm³.

The n−-type drift layer 6 is a semiconductor layer containing, for example, arsenic or phosphorus as n-type impurities. The concentration of the n-type impurity in the n−-type drift layer 6 is greater than or equal to 1.0×10¹²/cm³ and less than or equal to 1.0×10¹⁵/cm³.

The n-type carrier accumulation layer 5 is a semiconductor layer containing, for example, arsenic or phosphorus as n-type impurities. The concentration of the n-type impurity in the n-type carrier accumulation layer 5 is greater than or equal to 1.0×10¹³/cm³ and less than or equal to 1.0×10¹⁷/cm³. However, the n-type carrier accumulation layer 5 is not an essential configuration in the semiconductor device 101, and the p-type base layer 4 may be directly provided on the n−-type drift layer 6. The n-type carrier accumulation layer 5 reduces an energization loss when current flows. In the present specification, the n-type carrier accumulation layer 5 and the n−-type drift layer 6 may be collectively referred to as a drift layer.

The p-type base layer 4 is a semiconductor layer containing, for example, boron or aluminum as a p-type impurity. The concentration of the p-type impurity in the p-type base layer 4 is greater than or equal to 1.0×10¹²/cm³ and less than or equal to 1.0×10¹⁹/cm³. The p-type base layer 4 is in contact with a first gate insulating film 11 of the trench 10. On the side of the first main surface S1 of the p-type base layer 4, the n+-type source layer 3 is provided in contact with the first gate insulating film 11, and the p+-type contact layer is provided in a remaining region. The n+-type source layer 3 and the p+-type contact layer configure the first main surface of the semiconductor substrate. The p+-type contact layer is a region having a higher concentration of the p-type impurity than that of the p-type base layer 4. In the present specification, sometimes the p+-type contact layer and the p-type base layer 4 may be collectively referred to as a p-type base layer.

The n-type buffer layer 7 is a semiconductor layer having a higher concentration of n-type impurities than that of the n−-type drift layer 6. The n-type buffer layer 7 is provided to suppress punch-through by a depletion layer extending from the p-type base layer 4 toward the side of the second main surface S2 when the semiconductor device 101 is in an off state. The n-type impurity in the n-type buffer layer 7 is, for example, at least one of phosphorus (P) and proton (H+). The concentration of the n-type impurity in the n-type buffer layer 7 is greater than or equal to 1.0×10¹²/cm³ and less than or equal to 1.0×10¹⁸/cm³. The n-type buffer layer 7 is not an essential configuration in the semiconductor device 101, and the p-type collector layer 8 may be provided directly on the second main surface S2 side of the n−-type drift layer 6. In the present specification, sometimes the n-type buffer layer 7 and the n−-type drift layer 6 may be collectively referred to as a drift layer.

The p-type collector layer 8 is provided on the side of the second main surface S2 of the n-type buffer layer 7. That is, the p-type collector layer 8 is provided between the n−-type drift layer 6 and the second main surface S2. The p-type collector layer 8 is a semiconductor layer containing, for example, boron or aluminum as a p-type impurity. The concentration of the p-type impurity in the p-type collector layer 8 is greater than or equal to 1.0×10¹⁶/cm³ and less than or equal to 1.0×10²⁰/cm³. The p-type collector layer 8 configures the second main surface of the semiconductor substrate.

A first gate electrode 12 is embedded in some of 10 the plurality of trenches 10 through the first gate insulating film 11. The first gate insulating film 11 is disposed on inner walls of these trenches 10. A second gate electrode 15 is embedded in the remaining trench 10 through a second gate insulating film 14. The second gate insulating film 14 is disposed on the inner walls of these trenches 10. As illustrated in FIG. 1, the first gate electrode 12 is electrically connected to a first gate pad 30 through a first gate wiring 50. The second gate electrode 15 is electrically connected to a second gate pad 31 through a second gate wiring 51. Turn-on and turn-off timings of the first gate pad 30 and the second gate pad 31 are independently controlled by a controller (not illustrated).

When a gate drive voltage is applied to the first gate electrode 12 through the first gate pad 30, a channel is formed in the p-type base layer 4 that is in contact with the first gate insulating film 11, and an n-type accumulation layer is formed in the n-type carrier accumulation layer 5 and the n−-type drift layer 6 that are in contact with the first gate insulating film 11. Similarly, when the gate drive voltage is applied to the second gate electrode 15 through the second gate pad 31, the channel is formed in the p-type base layer 4 that is in contact with the second gate insulating film 14, and the n-type accumulation layer is formed in the n-type carrier accumulation layer 5 and the n−-type drift layer 6 that are in contact with the second gate insulating film 14.

The first gate electrode 12 and the second gate electrode 15 are formed by depositing polysilicon doped with n-type or p-type impurities. An impurity concentration of polysilicon in the first gate electrode 12 is greater than or equal to 1.0×10¹⁷/cm³ and less than or equal to 1.0×10²²/cm³. The impurity concentration of polysilicon in the second gate electrode 15 is higher than the impurity concentration of polysilicon in the first gate electrode 12. As a result, the semiconductor device 101 is characterized in that resistivity of the second gate electrode 15 is lower than resistivity of the first gate electrode 12. The impurity concentration of polysilicon in the second gate electrode 15 is, for example, greater than or equal to 1.0×10¹⁹/cm³ and less than or equal to 1.0×10²²/cm³, and desirably greater than or equal to 1.0×10²⁰/cm³ and less than or equal to 1.0×10²²/cm³.

Although two first gate electrodes 12 and two second gate electrodes 15 are illustrated in FIG. 1, the ratio between the first gate electrode 12 and the second gate electrode 15 is not limited to that illustrated in FIG. 1. In addition, the first gate electrode 12 and the second gate electrode 15 may not be alternately disposed.

As illustrated in FIG. 2, the interlayer insulating film 2 is provided on the first gate electrode 12 and the second gate electrode 15. Although not illustrated in FIG. 2, a barrier metal is formed on a region of the first main surface S1 where the interlayer insulating film 2 is not provided and on the interlayer insulating film 2. For example, the barrier metal is a conductor containing titanium (Ti). For example, the barrier metal is titanium nitride or TiSi obtained by alloying titanium or silicon (Si). The barrier metal is in ohmic contact with the n+-type source layer 3 and the p+-type contact layer, and is electrically connected to the n+-type source layer 3 and the p+-type contact layer.

The emitter electrode 1 as an upper-surface electrode is provided on the barrier metal. For example, the emitter electrode 1 is formed of an aluminum alloy such as an aluminum silicon alloy (Al—Si-based alloy). The emitter electrode 1 may be an electrode made of a plurality of layers of metal films in which a plating film is formed on an aluminum alloy film by electroless plating or electrolytic plating. At this point, for example, the plating film may be a nickel (Ni) plating film. When the emitter electrode 1 cannot be satisfactorily embedded in a fine region such as between the adjacent interlayer insulating films 2, tungsten having better embeddability than the emitter electrode 1 may be disposed in the region, and the emitter electrode 1 may be provided on the tungsten.

The emitter electrode 1 may be directly provided on the n+-type source layer 3 and the p+-type contact layer without providing the barrier metal. In addition, the barrier metal may be provided only on the n-type semiconductor layer such as the n+-type source layer 3. In the present specification, sometimes the barrier metal and the emitter electrode 1 may be collectively referred to as an emitter electrode.

A collector electrode 9 as a lower-surface electrode is provided on the side of the second main surface S2 of the p-type collector layer 8. Similarly to the emitter electrode 1, the collector electrode 9 may be made of an aluminum alloy or an aluminum alloy and a plating film. The collector electrode 9 may have a configuration different from that of the emitter electrode 1. The collector electrode 9 is in ohmic contact with the p-type collector layer 8 and is electrically connected to the p-type collector layer 8.

### <A-2. Manufacturing Process>

A method for manufacturing the semiconductor device 101 of the first preferred embodiment will be described. First, the semiconductor substrate 60 configuring the n−-type drift layer 6 is prepared. For example, the semiconductor substrate 60 is a floating zone FZ wafer manufactured by an FZ method or a magnetic applied CZochralski) MCZ wafer manufactured by an MCZ method, and may be an n-type wafer containing n-type impurities. For example, the semiconductor substrate 60 is a Si substrate. The concentration of the n-type impurity contained in the semiconductor substrate 60 is appropriately selected depending on a withstand voltage of the manufactured semiconductor device 101. For example, in the case of manufacturing the semiconductor device 101 having a withstand voltage of 1200 V, the concentration of the n-type impurity is adjusted such that a specific resistance of the n−-type drift layer 6 configuring the semiconductor substrate 60 is greater than or equal to about 40 Ω·cm and less than or equal to 120 Ω·cm. In a process for preparing the semiconductor substrate 60, the entire semiconductor substrate 60 is the n−-type drift layer 6. By implanting p-type or n-type impurity ions from the side of the first main surface S1 or the side of the second main surface S2 of the semiconductor substrate 60 and diffusing the impurity ions into the semiconductor substrate 60 by subsequent heat treatment or the like, the p-type or n-type semiconductor layer is formed to manufacture the semiconductor device 101.

Subsequently, by implanting n-type impurities such as phosphorus (P) from the side of the first main surface S1 of the semiconductor substrate 60, the n-type carrier accumulation layer 5 is formed on the side of the first main surface S1 of the n−-type drift layer 6. In addition, by implanting p-type impurities such as boron (B) from the side of the first main surface S1 of the semiconductor substrate 60, the p-type base layer 4 is formed on the side of the first main surface S1 of the n-type carrier accumulation layer 5. The n-type carrier accumulation layer 5 and the p-type base layer 4 are formed by implanting impurity ions into the semiconductor substrate and then diffusing the impurity ions by heat treatment. The n-type impurity and the p-type impurity are ion-implanted after mask processing is performed on the first main surface S1 of the semiconductor substrate 60, so that the n-type impurity and the p-type impurity are selectively formed on the side of the first main surface S1 of the semiconductor substrate 60. The mask processing is processing of forming a mask on the semiconductor substrate 60 by applying a resist on the semiconductor substrate 60 and forming an opening in a predetermined region of the resist using a photolithography technique. Ion implantation or etching is performed in a predetermined region of the semiconductor substrate 60 through the opening of the mask.

Subsequently, after the mask processing is performed on the first main surface S1 of the semiconductor substrate 60, the n-type impurity is selectively implanted into the first main surface side of the p-type base layer 4 to form the n+-type source layer 3. For example, the implanted n-type impurity is arsenic (As) or phosphorus (P). After the mask processing is performed on the first main surface S1 of the semiconductor substrate 60, the p-type impurity is selectively implanted into the side of the first main surface S1 of the p-type base layer 4 to form the p+-type contact layer. For example, the implanted p-type impurity is boron (B) or aluminum (Al).

Subsequently, a plurality of trenches 10 penetrating the p-type base layer 4 from the side of the first main surface S1 of the semiconductor substrate 60 and reaching the n−-type drift layer 6 are formed. The sidewalls of the plurality of trenches 10 penetrating the n+-type source layer 3 configure a part of the n+-type source layer 3. After an oxide film such as SiO2 is deposited on the semiconductor substrate 60, the mask processing is performed, etching is performed to form an opening in the oxide film at a portion where the trench 10 is formed, and the semiconductor substrate 60 is etched using the oxide film having the opening as a mask, whereby each trench 10 can be formed.

Subsequently, the semiconductor substrate 60 is heated in an atmosphere containing oxygen to form the first gate insulating film 11 on the inner wall of the trench 10 and the first main surface S1 of the semiconductor substrate 60. The first gate insulating film 11 formed on the first main surface S1 of the semiconductor substrate 60 is removed in a later process.

Subsequently, polysilicon doped with the n-type or p-type impurity by chemical vapor deposition (CVD) or the like is deposited in the plurality of trenches 10 to form the first gate electrode 12.

Subsequently, a mask in which the trench to be filled with the second gate electrodes 15 in the plurality of trenches 10 is opened is formed by the mask processing, and the first gate electrodes 12 in the trench to be filled with the second gate electrodes 15 is etched. Thereafter, the first gate insulating film 11 in the trench to be filled with the second gate electrode 15 is removed.

Subsequently, the semiconductor substrate 60 is heated in the atmosphere containing oxygen, and the second gate insulating film 14 is formed on the inner wall of the trench to be filled with the second gate electrode 15 and the first main surface S1 of the semiconductor substrate 60. The second gate insulating film 14 formed on the first main surface S1 of the semiconductor substrate is removed in a later process.

Subsequently, polysilicon doped with the n-type or p-type impurity by the chemical vapor deposition (CVD) or the like is deposited in the trench to be filled with the second gate electrode 15 to form the second gate electrode 15.

Subsequently, the interlayer insulating film 2 is formed on the trench 10. Thereafter, the first gate insulating film 11 and the second gate insulating film 14 that are formed on the first main surface S1 of the semiconductor substrate 60 are removed. For example, the interlayer insulating film 2 is SiO2. Then, a contact hole is formed in the deposited interlayer insulating film 2 by the mask processing. The contact hole is formed on the n+-type source layer 3 and the p+-type contact layer.

Subsequently, a barrier metal is formed on the first main surface S1 and the interlayer insulating film 2 of the semiconductor substrate 60, and the emitter electrode 1 is further formed on the barrier metal. The barrier metal is formed by depositing titanium nitride by physical vapor deposition (PVD) or the CVD.

For example, the emitter electrode 1 is formed by depositing an aluminum silicon alloy (Al—Si-based alloy) on the barrier metal by the PVD such as sputtering or vapor deposition. In addition, a nickel alloy (Ni alloy) may be further formed on the aluminum silicon alloy by electroless plating or electrolytic plating, and these two alloy layers may be used as the emitter electrode 1. As described above, a thick metal film can be easily formed as the emitter electrode 1 by plating, so that the heat capacity of the emitter electrode 1 can be increased to improve the heat resistance. The plating treatment forming the nickel alloy may be performed after the second main surface S2 side of the semiconductor substrate 60 is processed.

Subsequently, the second main surface S2 side of the semiconductor substrate 60 is ground to thin the semiconductor substrate 60 to a desired thickness. For example, the thickness of the ground semiconductor substrate 60 is greater than or equal to 80 μm and less than or equal to 200 μm.

Subsequently, the n-type impurity is implanted from the side of the second main surface S2 of the semiconductor substrate 60 to form the n-type buffer layer 7. Furthermore, the p-type impurity is implanted from the side of the second main surface S2 of the semiconductor substrate 60 to form the p-type collector layer 8.

For example, the n-type buffer layer 7 is formed by implanting one or both of a phosphorus (P) ion and a proton (H+). The proton is injected from the second main surface S2 of the semiconductor substrate 60 to a deep position by relatively low acceleration energy. In addition, the proton injection depth can be relatively easily changed by changing acceleration energy. For this reason, when the proton is injected a plurality of times while the acceleration energy is changed, the n-type buffer layer 7 having a width wider in the thickness direction of the semiconductor substrate 60 than that formed of phosphorus can be formed.

As compared with the proton, phosphorus can increase an activation rate as the n-type impurity. For this reason, when the n-type buffer layer 7 is formed with phosphorus, punch-through of the depletion layer can be more reliably prevented even in the thinned semiconductor substrate 60. In order to further thin the semiconductor substrate 60, preferably the n-type buffer layer 7 is formed by injecting both the proton and phosphorus, and at this time, the proton is injected at a position deeper from the second main surface S2 than phosphorus.

For example, the p-type collector layer 8 is formed by injecting boron (B). After the ion implantation from the side of the second main surface S2 of the semiconductor substrate 60, the second main surface S2 is irradiated with laser to perform laser annealing, so that implanted boron is activated to form the p-type collector layer 8. At this point, phosphorus for the n-type buffer layer 7 implanted at a relatively shallow position from the second main surface S2 of the semiconductor substrate 60 is also activated at the same time. On the other hand, the proton is activated at a relatively low annealing temperature higher than or equal to 350° C. and lower than or equal to 500° C., so that attention needs to be paid such that the entire semiconductor substrate 60 does not become higher than or equal to 350° C. except for a process for activating the proton after injecting the proton. Only the vicinity of the second main surface S2 of the semiconductor substrate 60 can be heated to a high temperature, so that the laser annealing can be used to activate the n-type impurity or the p-type impurity other than the proton after the proton injection.

Subsequently, the collector electrode 9 is formed on the second main surface S2 of the semiconductor substrate 60. The collector electrode 9 may be formed over the entire second main surface S2 of the semiconductor substrate 60. For example, the collector electrode 9 is formed by depositing an aluminum silicon alloy (Ai-Si-based alloy), titanium (Ti), or the like on the second main surface S2 of the semiconductor substrate 60 by the PVD such as the sputtering or the vapor deposition. Alternatively, the collector electrode 9 may be formed by laminating a plurality of metals such as an aluminum silicon alloy, titanium, nickel, or gold. In addition, a metal film may be further formed on the metal film formed by the PVD by electroless plating or electrolytic plating, and these two metal layers may serve as the collector electrode 9.

The semiconductor device 101 is manufactured by the above processes. A plurality of semiconductor devices 101 are manufactured in a matrix form on one n-type wafer. Thereafter, cutting is performed by laser dicing or blade dicing to obtain one semiconductor device 101.

### <A-3. Operation>

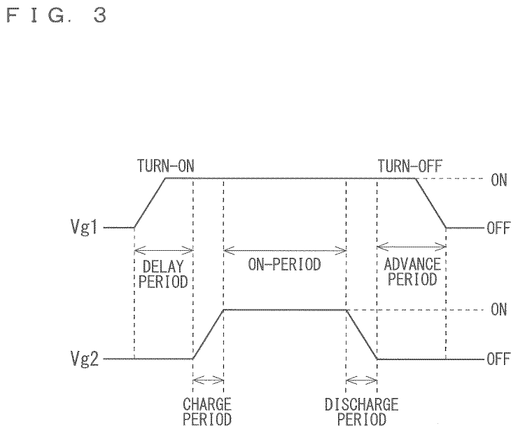

FIG. 3 is a view illustrating drive timing of the semiconductor device 101. In FIG. 3, Vg1 represents the voltage applied to the first gate pad 30 and the first gate electrode 12, and Vg2 represents the voltage applied to the second gate pad 31 and the second gate electrode 15. The controller (not illustrated) controls so as to turn on the second gate pad 31 at timing later than the first gate pad 30 and to turn off the second gate pad 31 at timing earlier than the first gate pad 30. That is, the second gate pad 31 is turned on after the first gate pad 30 is turned on, and the first gate pad 30 is turned off after the second gate pad 31 is turned off. A period during which the turn-off of the second gate pad 31 is delayed with respect to the turn-off of the first gate pad 30 is referred to as a delay period. A period during which the turn-on of the second gate pad 31 precedes the turn-on of the first gate pad 30 is referred to as an advance period.

In the semiconductor device 101, the resistivity of the second gate electrode 15 is lower than the resistivity of the first gate electrode 12, so that reduction of the gate current in the second gate electrode 15 can be reduced. As a result, the charge-discharge of gate capacitance parasitic in the second gate electrode 15 can be speeded up. That is, as illustrated in FIG. 3, the charge period and the discharge period of the gate capacitance parasitic on second gate electrode 15 can be made shorter than the charge period and the discharge period of the gate capacitance parasitic on the first gate electrode 12, respectively. Accordingly, the on period of the second gate electrode 15 becomes longer. When the second gate electrode 15 is turned on, an n-type accumulation layer is formed around the second gate electrode 15. The hole injected from the p-type collector layer 8 are hardly discharged from the emitter electrode 1 because the accumulation layer serves as a hole barrier, and the hole is accumulated in the n−-type drift layer 6. As a result, conductivity modulation is promoted and an on-voltage is reduced.

### <A-4. Modification>

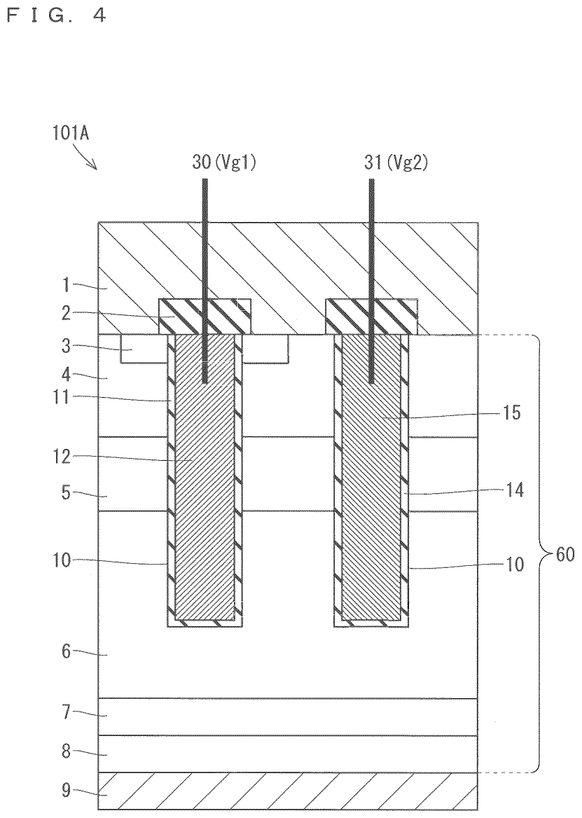

FIG. 4 is a sectional view illustrating a semiconductor device 101A according to a first modification of the first preferred embodiment. The top view of the semiconductor device 101A is similar to the top view of the semiconductor device 101 in FIG. 1, and the sectional view in FIG. 4 is a sectional view of the semiconductor device 101A taken along line A-A in FIG. 1. In the semiconductor device 101A, the n+-type source layer 3 is in contact with the first gate insulating film 11 but not in contact with the second gate insulating film 14. The configuration of the semiconductor device 101A other than the n+-type source layer 3 is similar to that of the semiconductor device 101.

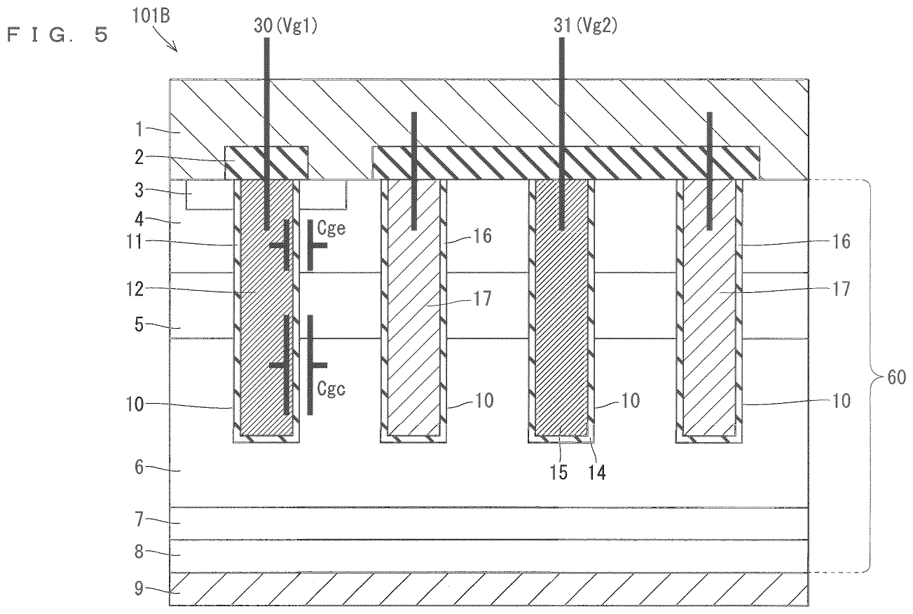

FIG. 5 is a sectional view illustrating a semiconductor device 101B according to a second modification of the first preferred embodiment. The top view of the semiconductor device 101B is similar to the top view of the semiconductor device 101 in FIG. 1, and the sectional view in FIG. 5 is a sectional view of the semiconductor device 101B taken along line A-A in FIG. 1. In the semiconductor device 101B, a trench emitter electrode 17 is embedded in some of the trenches 10 through an insulating film 16. That is, the semiconductor device 101B includes the trench 10 in which the first gate electrode 12 is embedded, the trench 10 in which the second gate electrode 15 is embedded, and the trench 10 in which the trench emitter electrode 17 is embedded. The trench emitter electrode 17 is electrically connected to the emitter electrode 1.

As illustrated in FIG. 5, in the semiconductor device 101B, the semiconductor region adjacent to the second gate insulating film 14 may be insulated from the emitter electrode 1 by the interlayer insulating film 2 and may not be electrically connected to the emitter electrode 1. Other configurations of the semiconductor device 101B are similar to those of the semiconductor device 101.

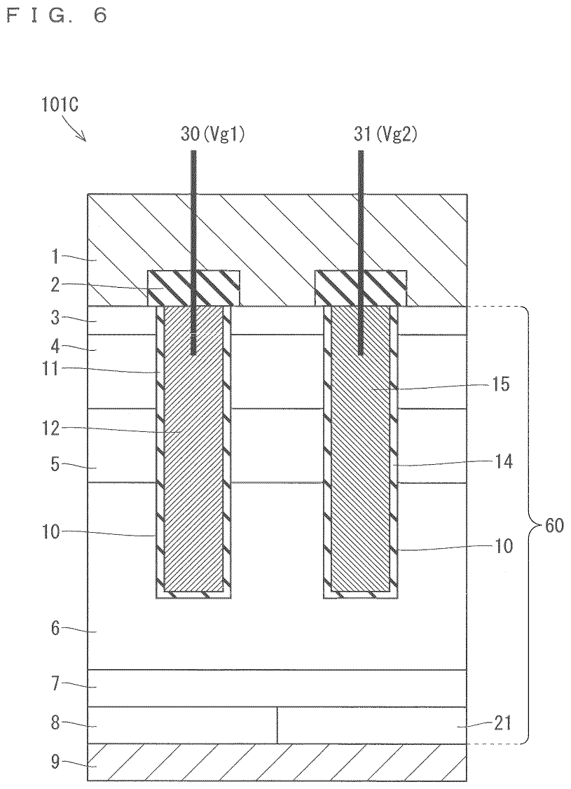

FIG. 6 is a sectional view illustrating a semiconductor device 101C according to a third modification of the first preferred embodiment. The top view of the semiconductor device 101C is similar to the top view of the semiconductor device 101 in FIG. 1, and the sectional view in FIG. 6 is a sectional view of the semiconductor device 101C taken along line A-A in FIG. 1.

The semiconductor device 101C configures a reverse conducting IGBT (RC-IGBT). In the semiconductor device 101C, an n-type cathode layer 21 is provided on the side of the second main surface S2 of the n-type buffer layer 7 in addition to the p-type collector layer 8. The configuration of the semiconductor device 101C other than the n-type cathode layer 21 is similar to that of the semiconductor device 101.

According to the semiconductor device 101C, the electron is injected by turning on the second gate electrode 15 for a short time before a diode recovery operation, and the hole in the n−-type drift layer 6 can be reduced by recombination, so that a recovery loss can be reduced. When the charge-discharge of the second gate electrode 15 is slow, the electron injection becomes too large, and a snapback phenomenon in which the current does not flow at a predetermined voltage is generated. However, in this configuration, the charge-discharge can be speeded up, so that the electron injection amount when the second gate electrode 15 is on can be reduced to prevent the snapback phenomenon.

The semiconductor device 101 of the first preferred embodiment configures the IGBT. However, the semiconductor device 101 may not include the p-type collector layer 8 and may configure a metal-oxide-semiconductor field-effect transistor (MOSFET). As an effect contributing to the unipolar MOSFET, the gate capacitance parasitic in the first gate electrode 12 can be shared by the second gate electrode 15, and the effective gate capacitance at the time of turn-on can be reduced, so that a switching loss is reduced. In addition, the charge-discharge of the second gate electrode 15 can be speeded up, so that a period during which the on-resistance is short can be lengthened to reduce the conduction loss.

As a material of the second gate electrode 15, amorphous silicon may be used instead of polysilicon. Amorphous silicon can reduce surface irregularities as compared with polysilicon. For this reason, when the second gate electrode 15 is made of amorphous silicon, the surface area of the second gate electrode 15 in contact with the second gate insulating film 14 is reduced. As a result, the gate capacitance parasitic on the second gate electrode 15 is reduced, and the charge-discharge of the gate capacitance is accelerated, so that the period during which the on-voltage is low becomes longer to improve the conduction loss.

As a material of the first gate electrode 12, amorphous silicon may be used instead of polysilicon.

As a material of the second gate electrode 15, metal may be used instead of polysilicon. When the second gate electrode 15 is made of metal, the resistivity of the second gate electrode 15 becomes small. For this reason, the charge-discharge of the gate capacitance parasitic in the second gate electrode 15 is accelerated, the period during which the on-voltage is low becomes longer to improve the conduction loss.

As the semiconductor substrate 60, a substrate made of a wide band gap semiconductor such as SiC, GaN, or Ga2O3 may be used instead of the Si substrate. In this case, the gate capacitance inversely proportional to the gate oxide film thickness tends to be larger than that of Si because the thickness of the gate oxide film can become about half of Si due to the difference in physical properties. For this reason, the effective effect of reducing the gate capacitance by the configuration of the present disclosure is large, and the switching loss is reduced. In addition, the charge-discharge of the gate capacitance is speeded up, so that the period during which the on-resistance is short becomes longer to reduce the conduction loss.

### B. Second Preferred Embodiment

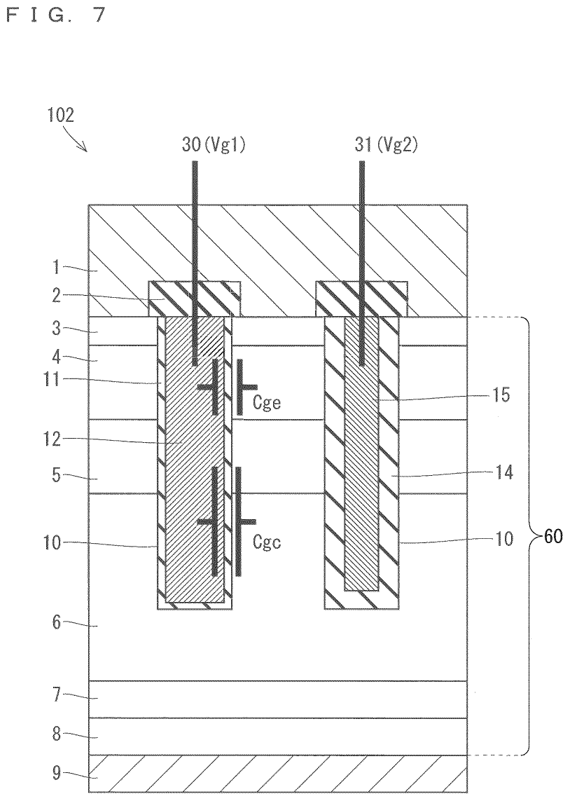

FIG. 7 is a sectional view illustrating a semiconductor device 102 according to a second preferred embodiment. The top view of the semiconductor device 102 is similar to the top view of the semiconductor device 101 in FIG. 1, and the sectional view of FIG. 7 is a sectional view of the semiconductor device 102 taken along line A-A in FIG. 1.

In the semiconductor device 102, the second gate insulating film 14 is thicker than the first gate insulating film 11. The configuration of the semiconductor device 102 other than the thickness of the second gate insulating film 14 is similar to that of the semiconductor device 101. In the semiconductor device 102, similarly to the semiconductor device 101, the resistivity of the second gate electrode 15 may be made lower than the resistivity of the first gate electrode 12 by making the impurity concentration of polysilicon in the second gate electrode 15 higher than the impurity concentration of polysilicon in the first gate electrode 12.

In the semiconductor device 102, the second gate insulating film 14 is thicker than the first gate insulating film 11, so that the gate capacitance parasitic on the second gate electrode 15 is smaller than the gate capacitance parasitic on the first gate electrode 12.

For example, the thickness of the first gate insulating film 11 is greater than or equal to 50 nm and less than or equal to 150 nm. For example, the thickness of the second gate insulating film 14 is greater than or equal to 150 nm and less than or equal to 500 nm, and desirably greater than or equal to 300 nm and less than or equal to 500 nm. When the thickness of the second gate insulating film 14 is greater than or equal to 2 times, preferably greater than or equal to 3 times the thickness of the first gate insulating film 11, the gate capacitance parasitic on the second gate electrode 15 can be sufficiently reduced. This speeds up the charge-discharge of the gate capacitance parasitic in the second gate electrode 15, so that the period during which the on-voltage is low becomes longer to improve the conduction loss.

At this point, “the gate capacitance parasitic in the second gate electrode 15” or “the gate capacitance parasitic in the first gate electrode 12” refers to a sum of gate-emitter capacitance Cge and gate-collector capacitance Cgc. However, in the semiconductor device 102, the gate-emitter capacitance Cge parasitic on the second gate electrode 15 may be smaller than the gate-emitter capacitance Cge parasitic on the first gate electrode 12. In addition, the gate-collector capacitance Cgc parasitic on the second gate electrode 15 may be smaller than the gate-collector capacitance Cgc parasitic on the first gate electrode 12.

In FIG. 7, the number of trenches 10 including the first gate electrodes 12 is the same as the number of trenches 10 including the second gate electrodes 15. However, the number of the trenches 10 is not limited to the same number. For example, in order to reduce the gate capacitance parasitic on the second gate electrode 15, the number of trenches 10 including the second gate electrode 15 may be smaller than the number of trenches 10 including the first gate electrode 12.

### C. Third Preferred Embodiment

### <C-1. Configuration>

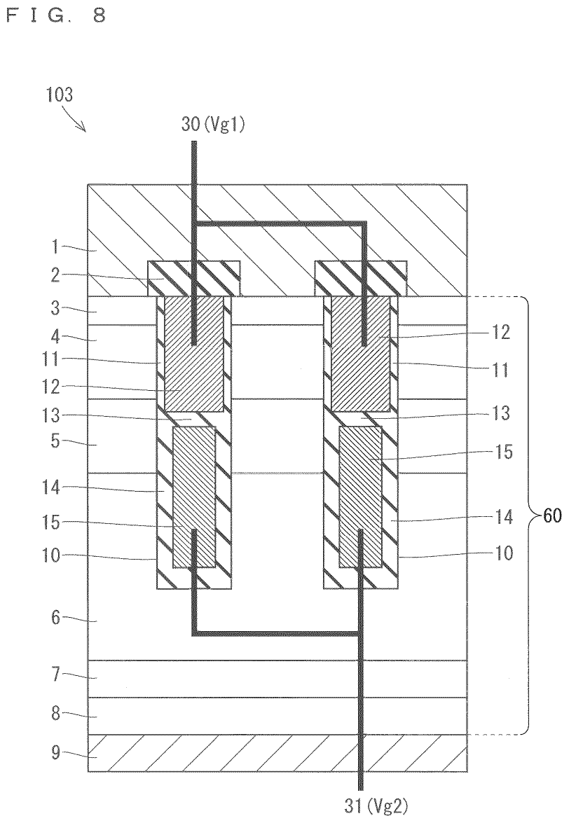

FIG. 8 is a sectional view illustrating a semiconductor device 103 according to a third preferred embodiment. The top view of the semiconductor device 103 is similar to the top view of the semiconductor device 101 in FIG. 1, and the sectional view of FIG. 8 is a sectional view of the semiconductor device 103 taken along line A-A in FIG. 1.

In the semiconductor device 103, the electrode inside each trench 10 has a two-stage structure of the upper-stage first gate electrode 12 and the lower-stage second gate electrode 15. Such a structure of the trench 10 is referred to as a split gate. The first gate electrode 12 and the second gate electrode 15 are insulated by a boundary insulating film 13. The configuration of the semiconductor device 103 other than the split gate is similar to that of the semiconductor device 101.

In general, because the electrode on the lower stage side of the split gate becomes an emitter potential, no accumulation layer is formed around the lower electrode, and the on-voltage is high. On the other hand, in the semiconductor device 103 of the third preferred embodiment, the second gate electrode 15 is disposed on the lower stage side of the split gate, and the accumulation layer is formed around the second gate electrode 15. For this reason, the electron injected through the channel formed by the first gate insulating film 11 on the upper stage side and the p-type base layer 4 is conducted with low resistance by the accumulation layer formed around the second gate electrode 15, so that the on-voltage is reduced.

In the above description, the semiconductor device 103 has been described as a configuration in which the split gate is applied to the semiconductor device 101 of the first preferred embodiment. However, the semiconductor device 103 may have a configuration in which the split gate is applied to the semiconductor device 102 of the second preferred embodiment. In FIG. 8, the second gate insulating film 14 is formed to be thicker than the first gate insulating film 11. In any configuration, the charge-discharge of the gate capacitance parasitic in the second gate electrode 15 can be speeded up, and the period during which the on-voltage is low can be extended to improve the conduction loss.

### <C-2. Modification>

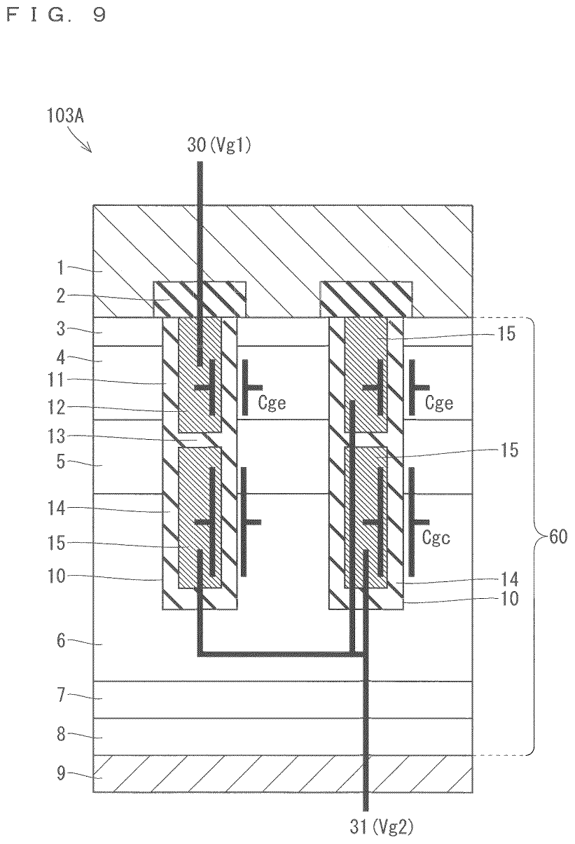

FIG. 9 is a sectional view illustrating a semiconductor device 103A according to a first modification of the third preferred embodiment. The top view of the semiconductor device 103A is similar to the top view of the semiconductor device 101 in FIG. 1, and the sectional view in FIG. 9 is a sectional view of the semiconductor device 103 A taken along line A-A in FIG. 1. In the semiconductor device 103A, both the upper stage side and the lower stage side of the split gate are the second gate electrodes 15 in some of the trenches 10. Other configurations of the semiconductor device 103A are similar to those of the semiconductor device 103. With such the configuration, the gate-emitter capacitance Cge parasitic in the first gate electrode 12 is reduced, so that the turn-on loss is reduced.

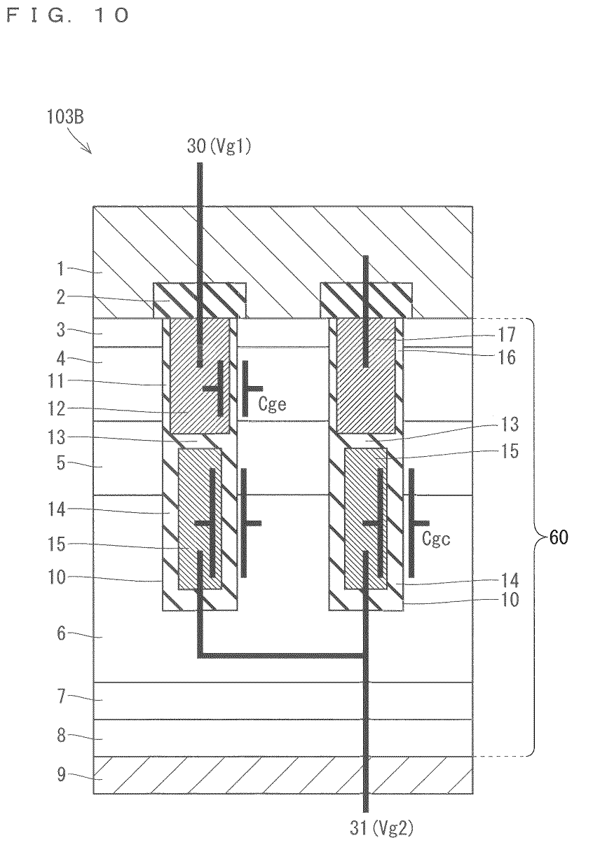

FIG. 10 is a sectional view illustrating a semiconductor device 103B according to a second modification of the third preferred embodiment. The top view of the semiconductor device 103B is similar to the top view of the semiconductor device 101 in FIG. 1, and the sectional view of FIG. 10 is a sectional view of the semiconductor device 103B taken along line A-A in FIG. 1.

In the semiconductor device 103B, the upper stage side of the split gate is the trench emitter electrode 17 in some of the trenches 10. The trench emitter electrode 17 is electrically connected to the emitter electrode. The insulating film 16 is formed between the trench emitter electrode 17 and the inner wall of the trench 10. Other configurations of the semiconductor device 103B are similar to those of the semiconductor device 103. With such the configuration, the gate-emitter capacitance Cge parasitic in the first gate electrode 12 is reduced, so that the turn-on loss is reduced. Furthermore, the gate-emitter capacitance Cge parasitic in the second gate electrode 15 is smaller than that in the semiconductor device 103A, so that the charge-discharge of the gate-emitter capacitance Cge parasitic in the second gate electrode 15 can be speeded up. As a result, the period during which the on-voltage is low becomes longer, and the conduction loss is improved.

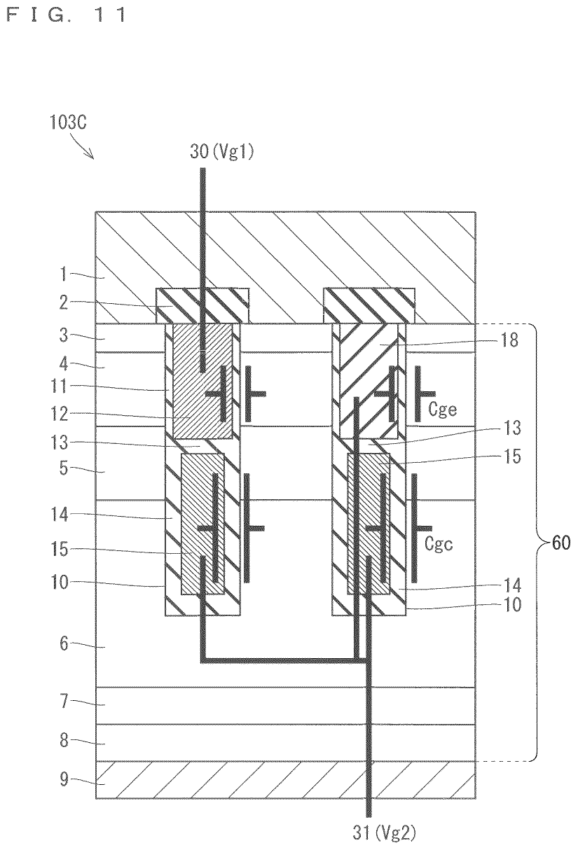

FIG. 11 is a sectional view illustrating a semiconductor device 103C according to a third modification of the third preferred embodiment. The top view of the semiconductor device 103C is similar to the top view of the semiconductor device 101 in FIG. 1, and the sectional view in FIG. 11 is a sectional view of the semiconductor device 103C taken along line A-A in FIG. 1.

In the semiconductor device 103C, the upper stage side of the split gate is filled with an insulator 18 in some of the trenches 10. According to the configuration of the semiconductor device 103B, the gate-emitter capacitance Cge is generated between the trench emitter electrode 17 and the second gate electrode 15. According to the configuration of the semiconductor device 103C, the gate-emitter capacitance Cge is generated between the second gate electrode 15 and the p-type base layer 4, but can be made smaller than the gate-emitter capacitance Cge generated between the trench emitter electrode 17 and the second gate electrode 15 in the semiconductor device 103B.

Accordingly, the charge-discharge of the gate-emitter capacitance Cge parasitic in the second gate electrode 15 can be speeded up, and the period of the low on-voltage can be lengthened.

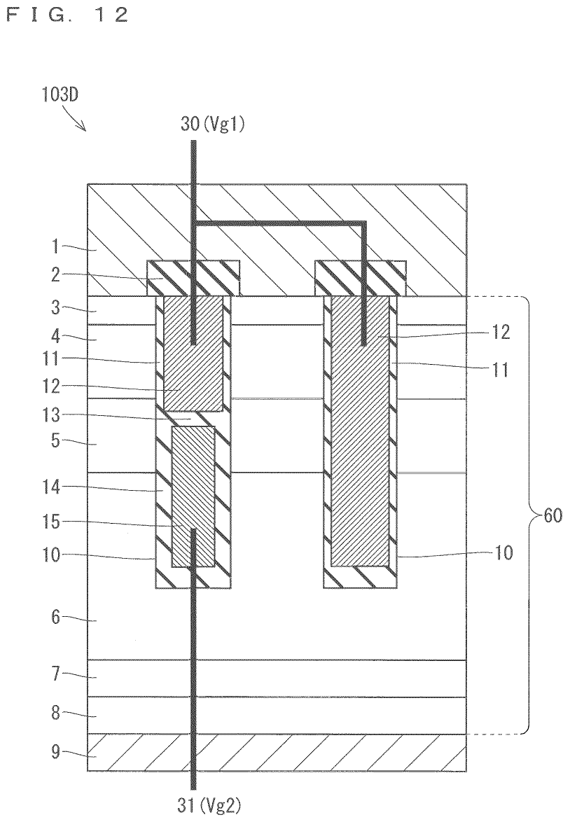

In the above description, the configuration in which the split gates are formed in all the trenches 10 has been described. However, as illustrated in the following modification, a configuration in which the split gate and a normal gate (hereinafter, also referred to as a “single-stage gate”) that is not the split gate are combined may be adopted. FIG. 12 is a sectional view illustrating a semiconductor device 103D according to a fourth modification of the third preferred embodiment. The top view of the semiconductor device 103D is similar to the top view of the semiconductor device 101 in FIG. 1, and the sectional view in FIG. 12 is a sectional view of the semiconductor device 103D taken along line A-A in FIG. 1.

In the semiconductor device 103D, the split gate including the upper-stage first gate electrode 12 and the lower-stage second gate electrode 15 is formed in some of the trenches 10. In the split gate, the first gate insulating film 11 is provided between the first gate electrode 12 and the inner wall of the trench 10, and the second gate insulating film 14 is provided between the second gate electrode 15 and the inner wall of the trench 10. The boundary insulating film 13 is provided between the first gate electrode 12 and the second gate electrode 15 to insulate the first gate electrode 12 and the second gate electrode 15 from each other. On the other hand, the first gate electrode 12 is formed in the remaining trenches 10 through the first gate insulating film 11.

In the case where the second gate electrode 15 is provided on the lower stage side of the split gate, when the second gate pad 31 is turned off, the accumulation layer is not formed around the second gate electrode 15, and the electron injection efficiency decreases. For this reason, the on-voltage during the period until the first gate pad 30 is turned off becomes high. In particular, when the off-voltage of the second gate pad 31 is large on the negative side, the p-type inversion layer is formed around the second gate electrode 15 on the lower stage side, so that there is a specific problem that, even when the first gate electrode 12 on the upper stage side is turned on, the electron injection is greatly suppressed to increase the on-voltage. On the other hand, in the semiconductor device 103D, the on-voltage in the period until the first gate pad 30 is turned off can be reduced by combining the split gate and the single-stage gate.

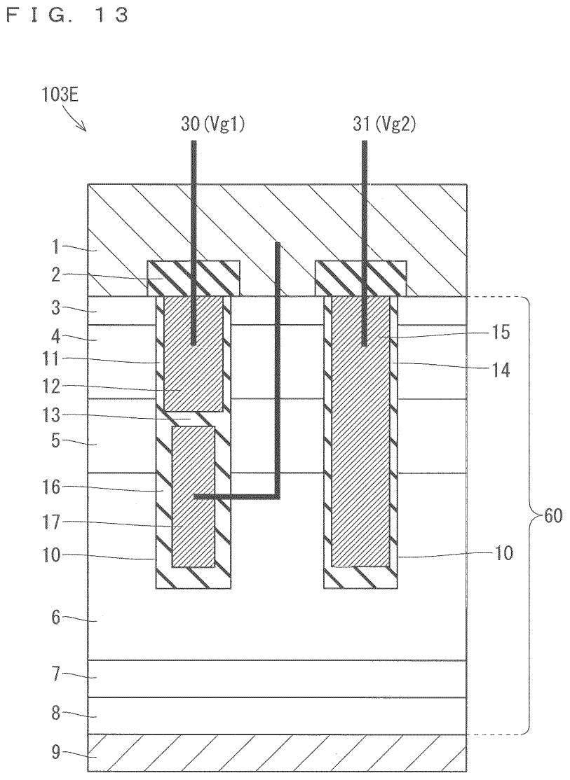

FIG. 13 is a sectional view illustrating a semiconductor device 103E according to a fifth modification of the third preferred embodiment. The top view of the semiconductor device 103E is similar to the top view of the semiconductor device 101 in FIG. 1, and the sectional view in FIG. 13 is a sectional view of the semiconductor device 103E taken along line A-A in FIG. 1.

In the semiconductor device 103E, the lower stage side of the split gate is the trench emitter electrode 17, and the electrode of the one-stage gate is the second gate electrode 15. The insulating film 16 is formed between the trench emitter electrode 17 and the inner wall of the trench 10. The second gate insulating film 14 is formed between the second gate electrode 15 and the inner wall of the trench 10. Other configurations of the semiconductor device 103E are similar to those of the semiconductor device 103D. In the semiconductor device 103E, the electrode of the one-stage gate is the second gate electrode 15, so that the electron is efficiently injected from the first gate electrode 12 on the upper stage side of the split gate even after the second gate pad 31 is turned off. In addition, the increase in the on-voltage after the second gate pad 31 is turned off is prevented.

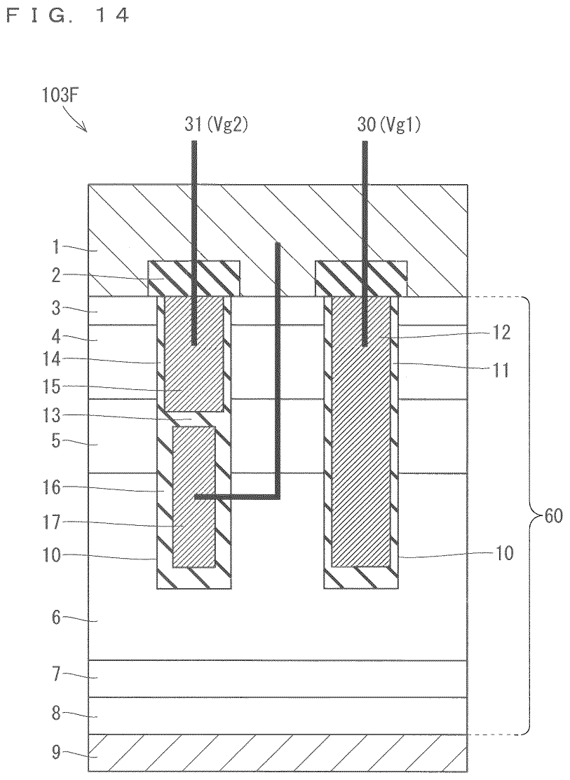

FIG. 14 is a sectional view illustrating a semiconductor device 103F according to a sixth modification of the third preferred embodiment. The top view of the semiconductor device 103F is similar to the top view of the semiconductor device 101 in FIG. 1, and the sectional view in FIG. 14 is a sectional view of the semiconductor device 103F taken along line A-A in FIG. 1.

In the semiconductor device 103F, the upper stage side of the split gate is the second gate electrode 15, and the electrode of the single-stage gate is the first gate electrode 12. The second gate insulating film 14 is formed between the second gate electrode 15 and the inner wall of the trench 10, and the first gate insulating film 11 is formed between the first gate electrode 12 and the inner wall of the trench 10. Other configurations of the semiconductor device 103F are similar to those of the semiconductor device 103E. In the semiconductor device 103F, even after the second gate pad 31 is turned off, more electrons are injected from the one-stage gate where the accumulation layer is formed. For this reason, the increase in the on-voltage after the second gate pad 31 is turned off is prevented.

### D. Fourth Preferred Embodiment

### <D-1. Configuration>

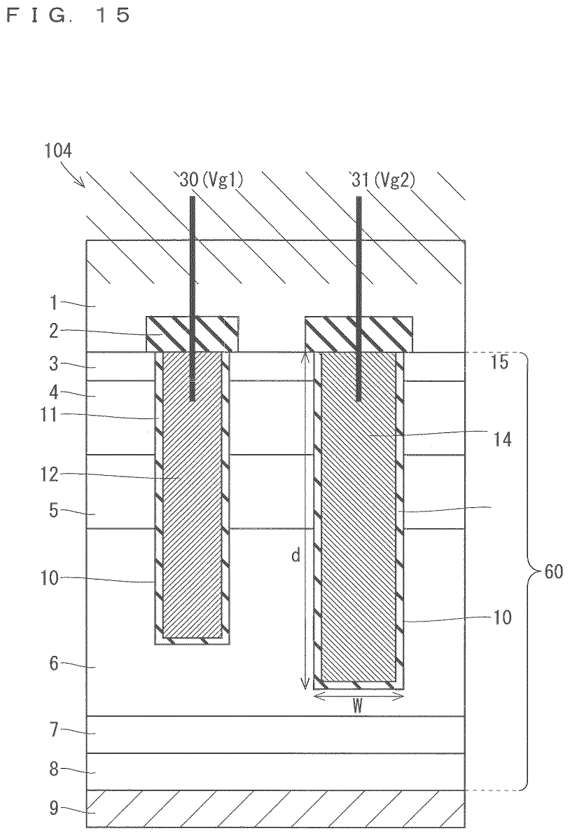

FIG. 15 is a sectional view illustrating a semiconductor device 104 according to a fourth preferred embodiment. The top view of the semiconductor device 104 is similar to the top view of the semiconductor device 101 in FIG. 1, and the sectional view in FIG. 15 is a sectional view of the semiconductor device 104 taken along line A-A in FIG. 1.

In the semiconductor device 104, the sectional area of the second gate electrode 15 is larger than the sectional area of the first gate electrode 12. Specifically, at least one of a depth d and a width w of the second gate electrode 15 is larger than those of the first gate electrode 12. When the sectional area of the second gate electrode 15 is increased, the resistivity of the second gate electrode 15 becomes smaller to speed up the charge-discharge of the gate capacitance parasitic in the second gate electrode 15. As a result, the period during which the on-voltage is low becomes longer, and the conduction loss is improved.

### <D-2. Modification>

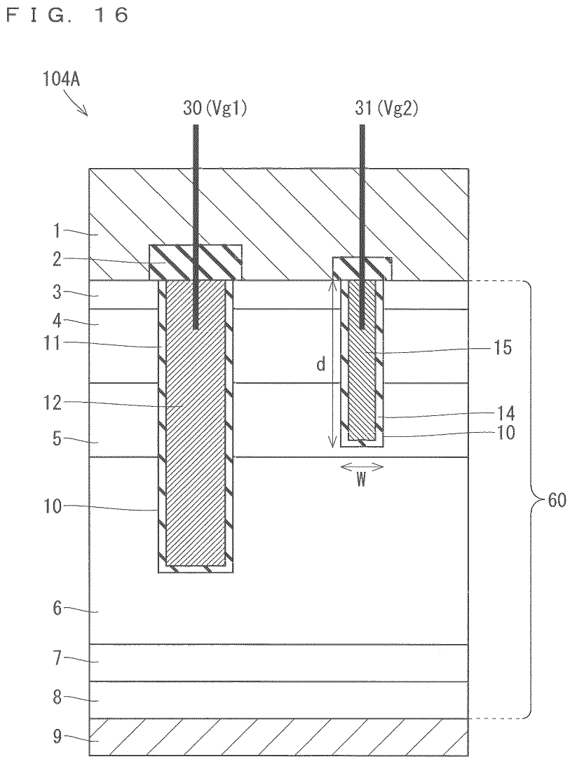

FIG. 16 is a sectional view illustrating a semiconductor device 104A according to a first modification of the fourth preferred embodiment. The top view of the semiconductor device 104A is similar to the top view of the semiconductor device 101 in FIG. 1, and the sectional view in FIG. 13 is a sectional view of the semiconductor device 104A taken along line A-A in FIG. 1.

In the semiconductor device 104A, the surface area of the second gate electrode 15 is smaller than the surface area of the first gate electrode 12. Specifically, at least one of the depth d and the width w of the second gate electrode 15 is smaller than those of the first gate electrode 12. The gate capacitance parasitic on the second gate electrode 15 can be reduced by reducing the surface area of the second gate electrode 15. As a result, the charge-discharge of the gate capacitance parasitic on the second gate electrode 15 is speeded up, and the period during which the on-voltage is low is lengthened to improve the conduction loss.

### E. Fifth Preferred Embodiment

### <E-1. Configuration>

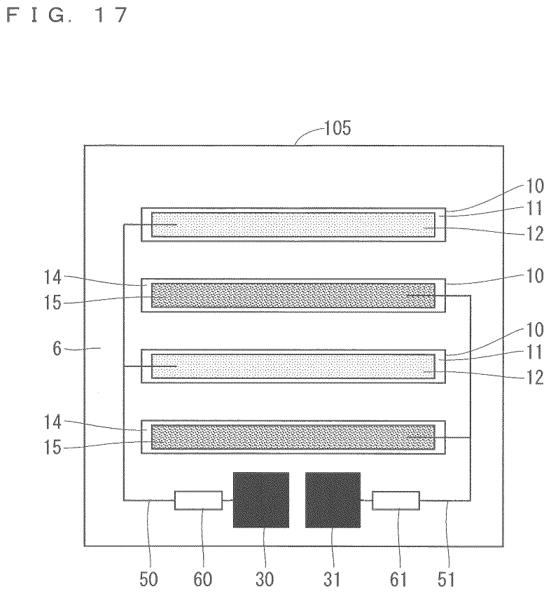

FIG. 17 is a top view illustrating a semiconductor device 105 according to a fifth preferred embodiment. The first gate electrode 12 is electrically connected to the first gate pad 30 through the first gate wiring 50 and a first built-in gate resistor 60. The second gate electrode 15 is electrically connected to the second gate pad 31 through the second gate wiring 51 and a second built-in gate resistor 61. The second built-in gate resistor 61 is smaller than the first built-in gate resistor 60. Accordingly, the charge-discharge of the gate capacitance parasitic in the second gate electrode 15 can be speeded up, the period during which the on-voltage is low becomes longer, and the conduction loss is improved.

### <E-2. Modification>

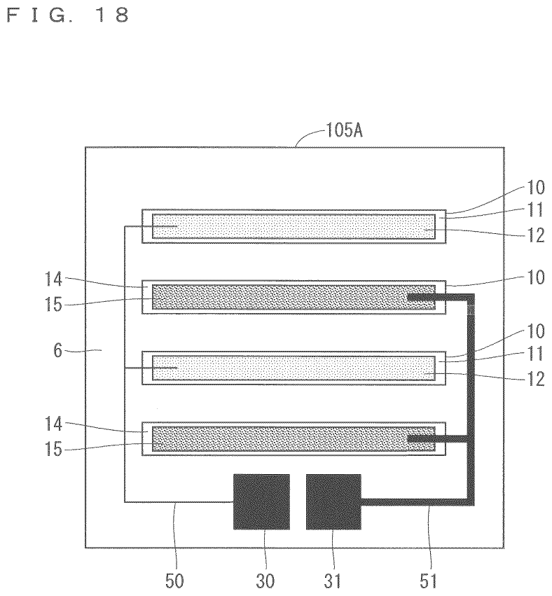

FIG. 18 is a top view illustrating a semiconductor device 105A according to a first modification of the fifth preferred embodiment. Unlike the semiconductor device 105, the semiconductor device 105A does not include the first built-in gate resistor 60 and the second built-in gate resistor 61. In the semiconductor device 105A, the sectional area of the second gate wiring 51 is larger than the sectional area of the first gate wiring 50. Specifically, the width of the second gate wiring 51 is larger than the width of the first gate wiring. Thus, the resistivity of the second gate wiring 51 becomes smaller than the resistivity of the first gate wiring 50. As a result, the resistance formed by the second gate wiring 51 becomes smaller than the resistance formed by the first gate wiring 50. Accordingly, the charge-discharge of the gate capacitance parasitic in the second gate electrode 15 can be speeded up, the period during which the on-voltage is low becomes longer, and the conduction loss is improved.

### F. Sixth Preferred Embodiment

### <F-1. Configuration>

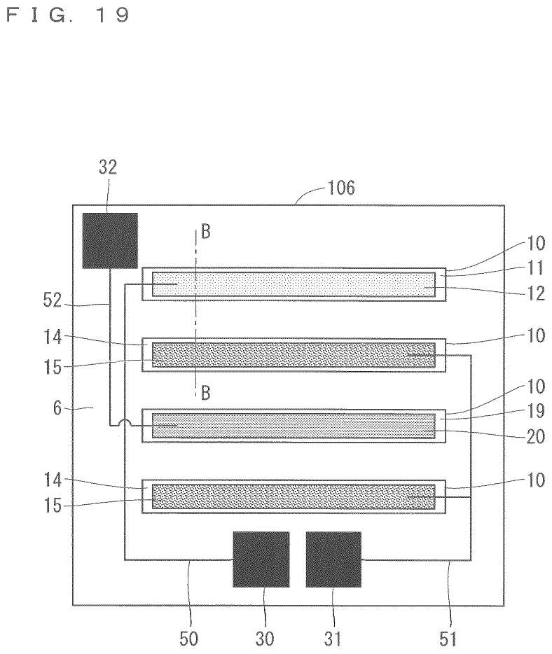

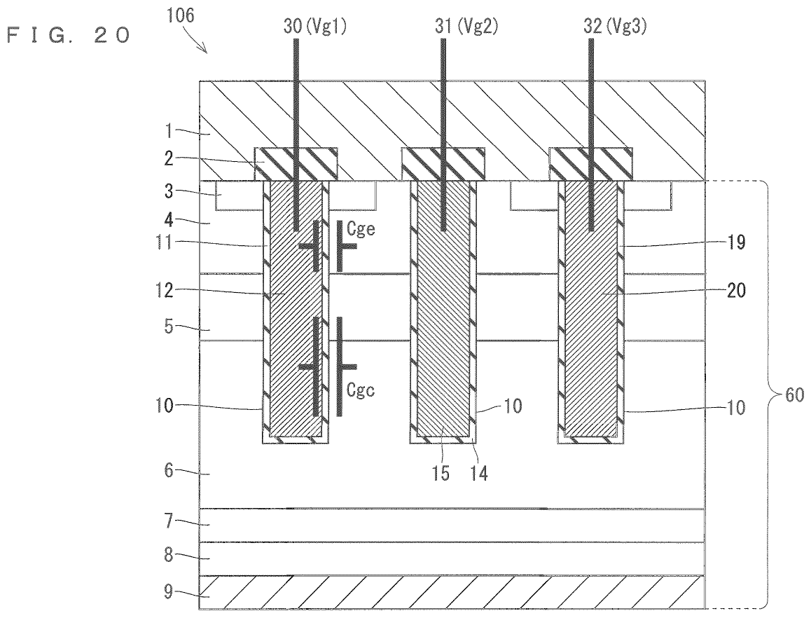

FIG. 19 is a top view illustrating a semiconductor device 106 according to a sixth preferred embodiment. FIG. 20 is a sectional view illustrating the semiconductor device 106 taken along line B-B in FIG. 19.

The semiconductor device 106 includes a third gate pad 32, a third gate insulating film 19, and a third gate electrode 20 in addition to the configuration of the semiconductor device 101 of the first preferred embodiment.

Among the plurality of trenches 10, the first gate electrode 12 is embedded in some of the trenches 10 through the first gate insulating film 11, the second gate electrode 15 is embedded in the other some of the trenches 10 through the second gate insulating film 14, and the third gate electrode 20 is embedded in the other some of the trenches 10 through the third gate insulating film 19.

The resistivity of the third gate electrode 20 is lower than the resistivity of the second gate electrode 15. Alternatively, the gate capacitance parasitic on the third gate electrode 20 is smaller than the gate capacitance parasitic on the second gate electrode 15. Accordingly, the charge period and the discharge period of the gate capacitance parasitic on the third gate electrode 20 are shorter than the charge period and the discharge period of the gate capacitance parasitic on the second gate electrode 15, respectively.

The third gate electrode 20 is electrically connected to the third gate pad 32 by a third gate wiring 52. The turn-on and turn-off timings of the first gate pad 30, the second gate pad 31, and the third gate pad 32 are independently controlled by the controller (not illustrated). That is, the semiconductor device 106 has a triple gate structure.

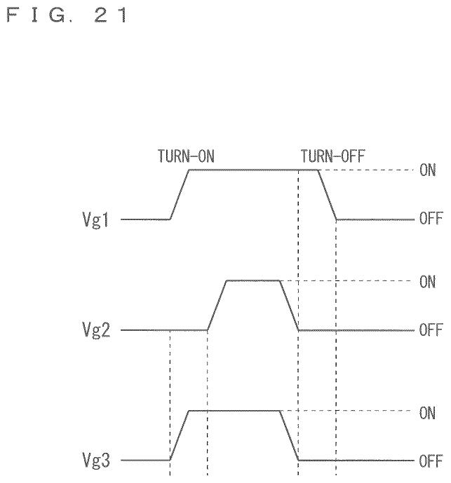

FIG. 21 is a view illustrating the drive timing of the semiconductor device 106. In FIG. 21, Vg3 represents the voltage applied to the third gate pad 32 and the third gate electrode 20. The third gate pad 32 is controlled by the controller (not illustrated) such that the third gate pad 32 is turned off at timing earlier than that of the first gate pad 30 and such that the third gate pad 32 is turned on at timing earlier than that of the second gate pad 31. That is, the second gate pad 31 is turned on after the third gate pad 32 is turned on, and the first gate pad 30 is turned off after the third gate pad 32 is turned off. The turn-on and turn-off timings of the first gate pad 30 and the second gate pad 31 are similar to those in the first preferred embodiment.

When the third gate pad 32 is turned off at timing earlier than that of the first gate pad 30, only the gate capacitance parasitic on the first gate electrode 12 becomes the gate capacitance in the off state, so that the gate capacitance becomes smaller to reduce the turn-off loss. When the third gate pad 32 is turned on at timing earlier than the second gate pad 31, the channel density is increased by the channel formed by the third gate electrode 20 and the electron injection amount is increased, so that the current time change is accelerated to reduce the turn-on loss.

### <F-2. Modification>

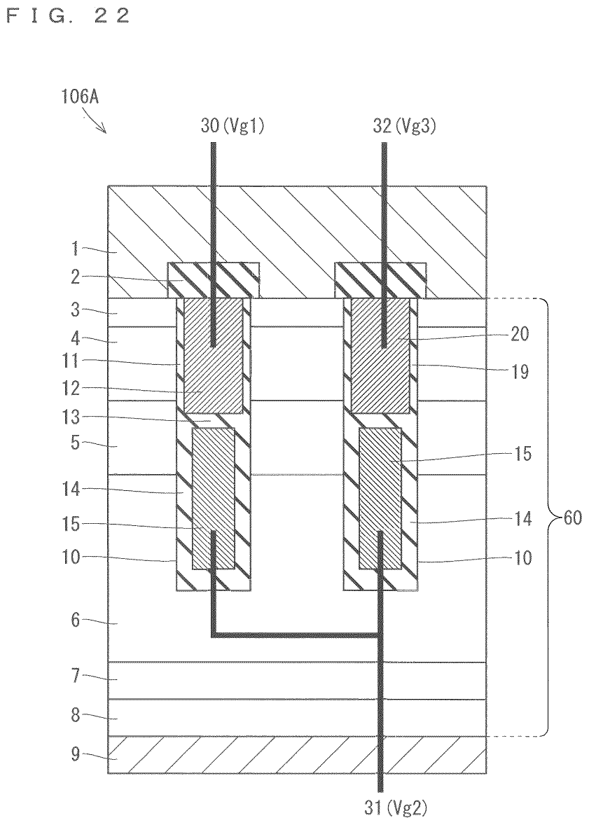

FIG. 22 is a sectional view illustrating a semiconductor device 106A according to a first modification of the sixth preferred embodiment. The semiconductor device 106A adopts a split gate structure in the semiconductor device 106 having the triple gate structure. In the trench 10, the second gate electrode 15 is embedded in the lower stage through the second gate insulating film 14, and the first gate electrode 12 is embedded in the upper stage through the first gate insulating film 11, or the third gate electrode 20 is embedded in the upper stage through the third gate insulating film 19.

In the semiconductor device 106A, because the second gate insulating film 14 is not in contact with the p-type base layer 4, the second gate electrode 15 does not contribute to the increase in channel density. For this reason, when the second gate electrode 15 is turned on with a delay from the first gate electrode 12 and the third gate electrode 20, the turn-on speed can be increased by the gate capacitance parasitic on the second gate electrode 15, and the turn-on loss can be reduced.

### G. Seventh Preferred Embodiment

### <G-1. Configuration>

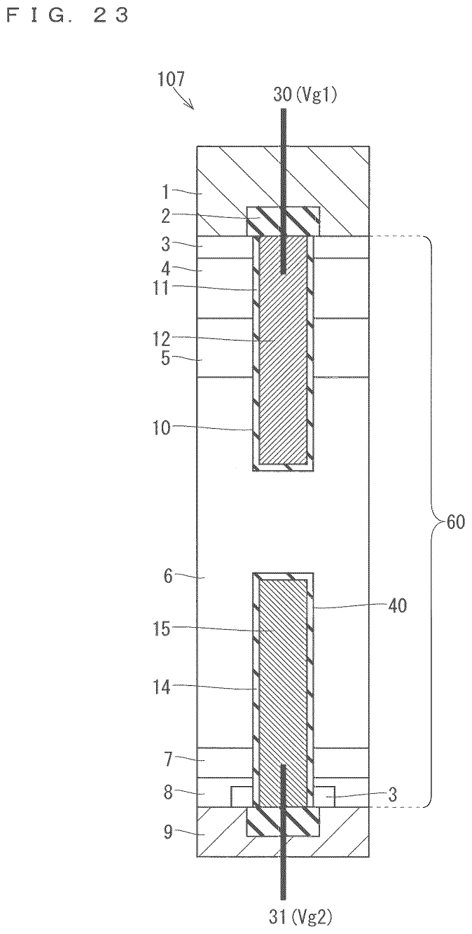

FIG. 23 is a sectional view illustrating a semiconductor device 107 according to a seventh preferred embodiment. The semiconductor device 107 adopts a double-sided gate structure in the semiconductor device 101 of the first preferred embodiment. In the semiconductor device 107, in addition to the trench 10 formed in the n−-type drift layer 6 from the first main surface S1, a trench 40 that penetrates the p-type collector layer 8 and the n-type buffer layer 7 from the second main surface S2 of the semiconductor substrate 60 to reach the n−-type drift layer 6 is formed in the semiconductor substrate 60. In order to distinguish between the two trenches, sometimes the trench 10 may be referred to as a first trench, and the trench 40 may be referred to as a second trench.

The first gate insulating film 11 is formed on the inner wall of the trench 10, and the first gate electrode 12 is embedded in the trench 10 through the first gate insulating film 11. The second gate insulating film 14 is formed on the inner wall of the trench 40, and the second gate electrode 15 is embedded in the trench 10 through the second gate insulating film 14. As described above, the semiconductor device 107 also has the gate structure on the side of the second main surface S2 (back surface side) of the semiconductor substrate 60.

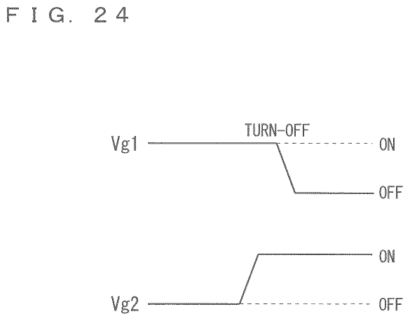

FIG. 24 is a view illustrating the drive timing of the semiconductor device 107. In FIG. 24, Vg1 represents the voltage applied to the first gate pad 30 and the first gate electrode 12, and Vg2 represents the voltage applied to the second gate pad 31 and the second gate electrode 15. During the turn-off, the second gate pad 31 is controlled by the controller (not illustrated) such that the second gate pad 31 is turned on at timing earlier than the turn-off of the first gate pad 30. That is, the first gate pad 30 is turned off after the second gate pad 31 is turned on.

In the double-sided gate structure, when the second gate pad 31 is turned on during the turn-off, the electron is discharged through the channel formed on the back surface side, so that the electron density on the back surface side is reduced. Accordingly, the turn-off loss is reduced because the hole density decreases so as to keep the charge neutral. On the other hand, because the hole density decreases to increase the on-voltage, desirably the charge period of the gate capacitance parasitic on the second gate pad 31 is shorter, namely, the timing of the turn-on of the second gate pad 31 is later.

In the semiconductor device 107, similarly to the semiconductor device 101 of the first preferred embodiment, the resistivity of the second gate electrode 15 is made lower than the resistivity of the first gate electrode 12. Alternatively, in the semiconductor device 107, similarly to the semiconductor device 102 of the second preferred embodiment, the gate capacitance parasitic on the second gate electrode 15 is made smaller than the gate capacitance parasitic on the first gate electrode 12. Accordingly, in the semiconductor device 107, the charge of the gate capacitance parasitic on the second gate electrode 15 can be speeded up, so that the timing of the turn-on of the second gate pad 31 can be delayed. As described above, according to the semiconductor device 107, the period during which the hole density is high, namely, the period during which the on-voltage is low can be lengthened, and the conduction loss can be improved.

### <G-2. Modification>

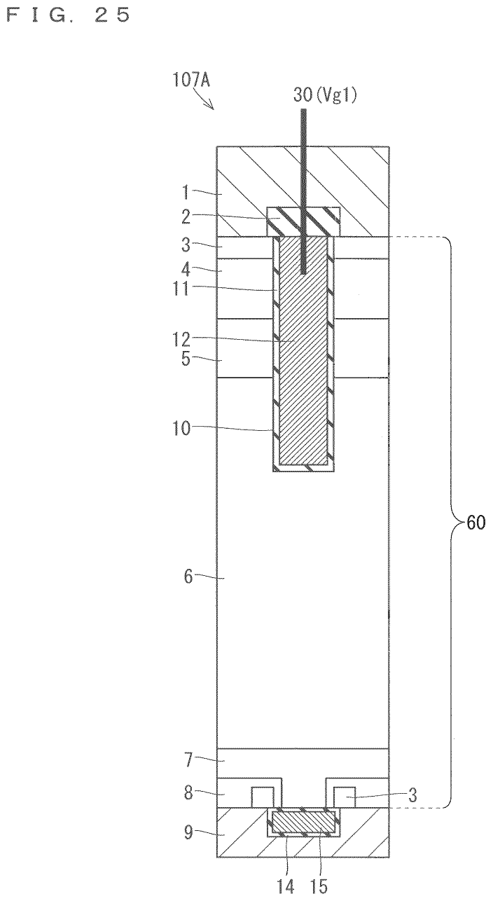

FIG. 25 is a sectional view illustrating a semiconductor device 107A according to a first modification of the seventh preferred embodiment. In the semiconductor device 107A, the gate structure on the back side of the semiconductor device 107 is not a trench type but a planar type. When the gate structure on the back surface side is made the planar type, the manufacturing process of the trench 40 on the back surface having high manufacturing difficulty can be reduced, and the manufacturing cost can be reduced.

Although the preferred embodiments and the like have been described in detail above, the present invention is not limited to the above-described preferred embodiments and the like, and various modifications and substitutions can be made to the above-described preferred embodiments and the like without departing from the scope described in the claims. Furthermore, the features of the semiconductor devices according to the respective preferred embodiments can be appropriately combined.

Hereinafter, various aspects of the present disclosure will be collectively described as appendixes.

### Appendix 1

A semiconductor device including:
a semiconductor substrate including a first main surface and a second main surface opposite to the first main surface;
an upper-surface electrode formed on the first main surface of the semiconductor substrate;
a lower-surface electrode formed on the second main surface of the semiconductor substrate;
a first gate pad; and
a second gate pad controlled independently of the first gate pad,
in which the semiconductor substrate includes
   a first-conductivity-type drift layer,
   a second-conductivity-type base layer formed on a side of the first main surface of the drift layer,
   a first-conductivity-type source layer formed on the side of the first main surface of the base layer,
   a plurality of first trenches that penetrate the base layer from the source layer to reach the drift layer, and
   a gate electrode embedded in each of the plurality of first trenches through an insulating film,
the gate electrode includes
   a first gate electrode electrically connected to the first gate pad, and
   a second gate electrode electrically connected to the second gate pad, and
a charge period and a discharge period of gate capacitance parasitic on the second gate electrode are shorter than a charge period and a discharge period of gate capacitance parasitic on the first gate electrode, respectively.

### Appendix 2

The semiconductor device described in Appendix 1, in which resistivity of the second gate electrode is lower than resistivity of the first gate electrode.

### Appendix 3

The semiconductor device described in Appendix 2, in which impurity concentration of a semiconductor material configuring the second gate electrode is higher than impurity concentration of a semiconductor material configuring the first gate electrode.

### Appendix 4

The semiconductor device described in Appendix 2, in which a sectional area of the second gate electrode is larger than a sectional area of the first gate electrode.

### Appendix 5

The semiconductor device described in Appendix 2, in which the second gate electrode is made of metal.

### Appendix 6

The semiconductor device described in Appendix 1, in which the gate capacitance parasitic on the second gate electrode is smaller than the gate capacitance parasitic on the first gate electrode.

### Appendix 7

The semiconductor device described in Appendix 6, in which a second gate insulating film that is the insulating film formed between the second gate electrode and the inner wall of the first trench is thicker than a first gate insulating film that is the insulating film formed between the first gate electrode and the inner wall of the first trench.

### Appendix 8

The semiconductor device described in Appendix 6, in which a surface area of the second gate electrode is smaller than a surface area of the first gate electrode.

### Appendix 9

The semiconductor device described in Appendix 6, in which the second gate electrode is made of amorphous silicon.

### Appendix 10

The semiconductor device described in Appendix 1, further including:
a first built-in gate resistor provided between the first gate electrode and the first gate pad; and
a second built-in gate resistor provided between the second gate electrode and the second gate pad,
in which the second built-in gate resistor is smaller than the first built-in gate resistor.

### Appendix 11

The semiconductor device described in Appendix 10, in which
the first built-in gate resistor includes a first gate wiring that connects the first gate electrode and the first gate pad,
the second built-in gate resistor includes a second gate wiring that connects the second gate electrode and the second gate pad, and
a resistivity of the second gate wiring is smaller than a resistivity of the first gate wiring.

### Appendix 12

The semiconductor device described in any one of Appendixes 1 to 11, in which in at least one first trench among the plurality of first trenches, the second gate electrode is embedded in a lower stage, the first gate electrode is embedded in an upper stage, and a boundary insulating film that insulates the first gate electrode and the second gate electrode from each other is provided between the first gate electrode and the second gate electrode.

### Appendix 13

The semiconductor device described in any one of Appendixes 1 to 12, in which
the second gate pad is turned on after the first gate pad is turned on, and
the first gate pad is turned off after the second gate pad is turned off.

### Appendix 14

The semiconductor device described in any one of Appendixes 1 to 13, further including a third gate pad controlled independently of the first gate pad and the second gate pad,
in which the gate electrode includes a third gate electrode electrically connected to the third gate pad, and
a charge period and a discharge period of the gate capacitance parasitic on the third gate electrode are shorter than a charge period and a discharge period of the gate capacitance parasitic on the second gate electrode, respectively.

### Appendix 15

The semiconductor device described in Appendix 14, in which
the second gate pad is turned on after the third gate pad is turned on, and
the first gate pad is turned off after the third gate pad is turned off.

### Appendix 16

The semiconductor device described in any one of Appendixes 1 to 11, in which
the semiconductor substrate includes at least one second trench reaching the drift layer from the second main surface, and
the second gate electrode is embedded inside the second trench instead of the first trench.

### Appendix 17

The semiconductor device described in Appendix 16, in which the first gate pad is turned off after the second gate pad is turned on.

### Appendix 18

The semiconductor device described in any one of Appendixes 1 to 17, in which the semiconductor device is an RC-IGBT.

### Appendix 19

The semiconductor device described in any one of Appendixes 1 to 17, in which the semiconductor device is a MOSFET.

### Appendix 20

The semiconductor device described in any one of Appendixes 1 to 19, in which the semiconductor substrate is made of a wide band gap semiconductor.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate including a first main surface and a second main surface opposite to the first main surface;
an upper-surface electrode formed on the first main surface of the semiconductor substrate;
a lower-surface electrode formed on the second main surface of the semiconductor substrate;
a first gate pad; and
a second gate pad controlled independently of the first gate pad,
wherein the semiconductor substrate includes
a first-conductivity-type drift layer,
a second-conductivity-type base layer formed on a side of the first main surface of the drift layer,
a first-conductivity-type source layer formed on the side of the first main surface of the base layer,
a plurality of first trenches that penetrate the base layer from the source layer to reach the drift layer, and
a gate electrode embedded in each of the plurality of first trenches through an insulating film,
the gate electrode includes
a first gate electrode electrically connected to the first gate pad, and
a second gate electrode electrically connected to the second gate pad, and
a charge period and a discharge period of gate capacitance parasitic on the second gate electrode are shorter than a charge period and a discharge period of gate capacitance parasitic on the first gate electrode, respectively.

2. The semiconductor device according to claim 1, wherein resistivity of the second gate electrode is lower than resistivity of the first gate electrode.

3. The semiconductor device according to claim 2, wherein impurity concentration of a semiconductor material configuring the second gate electrode is higher than impurity concentration of a semiconductor material configuring the first gate electrode.

4. The semiconductor device according to claim 2, wherein a sectional area of the second gate electrode is larger than a sectional area of the first gate electrode.

5. The semiconductor device according to claim 2, wherein the second gate electrode is made of metal.

6. The semiconductor device according to claim 1, wherein the gate capacitance parasitic on the second gate electrode is smaller than the gate capacitance parasitic on the first gate electrode.

7. The semiconductor device according to claim 6, wherein a second gate insulating film that is the insulating film formed between the second gate electrode and an inner wall of the first trench is thicker than a first gate insulating film that is the insulating film formed between the first gate electrode and the inner wall of the first trench.

8. The semiconductor device according to claim 6, wherein a surface area of the second gate electrode is smaller than a surface area of the first gate electrode.

9. The semiconductor device according to claim 6, wherein the second gate electrode is made of amorphous silicon.

10. The semiconductor device according to claim 1, further comprising:
a first built-in gate resistor provided between the first gate electrode and the first gate pad; and
a second built-in gate resistor provided between the second gate electrode and the second gate pad,
wherein the second built-in gate resistor is smaller than the first built-in gate resistor.

11. The semiconductor device according to claim 10, wherein
the first built-in gate resistor includes a first gate wiring that connects the first gate electrode and the first gate pad,
the second built-in gate resistor includes a second gate wiring that connects the second gate electrode and the second gate pad, and
a resistivity of the second gate wiring is smaller than a resistivity of the first gate wiring.

12. The semiconductor device according to claim 1, wherein in at least one first trench of the plurality of first trenches, the second gate electrode is embedded in a lower stage, the first gate electrode is embedded in an upper stage, and a boundary insulating film that insulates the first gate electrode and the second gate electrode from each other is provided between the first gate electrode and the second gate electrode.

13. The semiconductor device according to claim 1, wherein
the second gate pad is turned on after the first gate pad is turned on, and
the first gate pad is turned off after the second gate pad is turned off.

14. The semiconductor device according to claim 1, further comprising a third gate pad controlled independently of the first gate pad and the second gate pad,
wherein the gate electrode includes a third gate electrode electrically connected to the third gate pad, and
a charge period and a discharge period of the gate capacitance parasitic on the third gate electrode are shorter than a charge period and a discharge period of the gate capacitance parasitic on the second gate electrode, respectively.

15. The semiconductor device according to claim 14, wherein
the second gate pad is turned on after the third gate pad is turned on, and
the first gate pad is turned off after the third gate pad is turned off.

16. The semiconductor device according to claim 1, wherein
the semiconductor substrate includes at least one second trench reaching the drift layer from the second main surface, and
the second gate electrode is embedded inside the second trench instead of the first trench.

17. The semiconductor device according to claim 16, wherein the first gate pad is turned off after the second gate pad is turned on.

18. The semiconductor device according to claim 1, wherein the semiconductor device is an RC-IGBT.

19. The semiconductor device according to claim 1, wherein the semiconductor device is a MOSFET.

20. The semiconductor device according to claim 1, wherein the semiconductor substrate is made of a wide band gap semiconductor.
